(19) United States
(12) Patent Application Publication
(10) Pub. No.: US 2026/0032807 A1
(43) Pub. Date: Jan. 29, 2026

(54) PIN ARRANGEMENT STRUCTURE, PACKAGE SUBSTRATE, AND PACKAGE STRUCTURE

(71) Applicant: Glenfly Tech Co., Ltd., Shanghai (CN)

(72) Inventors: Bowen SHEN, Shanghai (CN); Xiaoping ZHANG, Shanghai (CN); Jianhang HU, Shanghai (CN); Jun WANG, Shanghai (CN)

(21) Appl. No.: 19/080,218

(22) Filed: Mar. 14, 2025

(30) Foreign Application Priority Data
Jul. 26, 2024 (CN) 202411018988.4

(51) Int. Cl. H05K 1/02

(52) U.S. Cl. CPC H05K 1/023; H05K 2201/10704

(57) ABSTRACT

The present disclosure relates to a pin arrangement structure, a package substrate, and a package structure, and relates to the field of package technologies. The pin arrangement structure includes a first pin array region. First pin units and second pin units in the first pin array region are sequentially arranged alternately in a first direction, and the first pin units and the second pin units are both provided with high-speed single-ended signal pins. A number of pins of the first pin units in a second direction is greater than a number of pins of the second pin units in the second direction, two adjacent second pin units are staggered in the first direction, and first reference ground pins are arranged at other pin positions of the first pin array region. Therefore, isolation is formed between the high-speed single-ended signal pins, improving isolation between signals and reducing crosstalk between the signals. At the same time, compared with existing arrangement, the arrangement reduces the number of pins and saves a region area of the pins.

### CROSS REFERENCE TO RELATED APPLICATIONS

This application claims priority under 35 U.S.C. § 119 to Chinese Patent Application No. 2024110189884, filed on Jul. 26, 2024, the entire content of which is incorporated herein in its entirety.

### TECHNICAL FIELD

The present disclosure relates to the field of package technologies, and in particular, to a pin arrangement structure, a package substrate, and a package structure.

### BACKGROUND

With widespread use of chips, more attention has been paid to the design of pins of circuit boards in the chips.

The design of pins is crucial in the design of chip packaging. For example, some chips include a high-speed double data rate (DDR) interface, and each byte high-speed data signal set of the DDR interface generally has a plurality of high-speed single-ended signal pins. When the plurality of high-speed single-ended signal pins are arranged, in order to provide a reference ground pin for each high-speed single-ended signal pin, the arrangement of the high-speed single-ended signal pins occupies a larger number of pins, resulting in a larger occupied area. In an existing manner of solve the problem of a larger number of high-speed single-ended signal pins, the high-speed single-ended signal pins are arranged in an array and arranged in close proximity, and there is no reference ground pin isolation between adjacent high-speed single-ended signal interface pins, resulting in greater crosstalk between the high-speed single-ended signal pins.

Therefore, how to achieve a small number of pins and reduce signal crosstalk has become an urgent technical problem for those skilled in the art.

### SUMMARY

Based on this, there is a need to provide a pin arrangement structure, a package substrate, and a package structure with respect to the problems of a large number of pins and presence of signal crosstalk in the prior art.

In order to achieve the above objective, on the one hand, the present disclosure provides a pin arrangement structure, including a first pin array region, the first pin array region including: first pin units and second pin units sequentially arranged alternately in a first direction; the first pin units and the second pin units being both provided with high-speed single-ended signal pins, a number of pins of the first pin units in a second direction being greater than a number of pins of the second pin units in the second direction, two adjacent second pin units being staggered in the first direction, and first reference ground pins being arranged at other pin positions of the first pin array region.

The pin arrangement structure includes a first pin array region. First pin units and second pin units in the first pin array region are sequentially arranged alternately in a first direction, and the first pin units and the second pin units are both provided with high-speed single-ended signal pins. A number of pins of the first pin units in a second direction is greater than a number of pins of the second pin units in the second direction, two adjacent second pin units are staggered in the first direction, and first reference ground pins are arranged at other pin positions of the first pin array region. Therefore, isolation is formed between the high-speed single-ended signal pins, improving isolation between signals and reducing crosstalk between the signals. At the same time, compared with existing arrangement, the arrangement reduces the number of pins and saves a region area of the pins.

In an embodiment, the pin arrangement structure further includes: a second pin array region located on one side of the first pin array region, the second pin array region including:
at least one third pin unit, the third pin unit being provided with high-speed differential signal pins, and the third pin unit being adjacent to the first reference ground pins in the second direction; and
second reference ground pins surrounding the third pin unit jointly with the first reference ground pins.

In an embodiment, the second pin array region further includes: third reference ground pins, the third reference ground pins being adjacent to the second pin units in the second direction.

In an embodiment, the pin arrangement structure further includes: a third pin array region, the third pin array region including the first pin array region and the second pin array region; and
the third pin array region further includes fourth pin units and fourth reference ground pins, the fourth pin units being provided with differential signal pins, and the fourth reference ground pins surrounding the fourth pin units; or the fourth reference ground pins surround the fourth pin units jointly with the second reference ground pins and/or the first reference ground pins.

In an embodiment, when a plurality of third pin units are provided, the plurality of third pin units are arranged at intervals in the first direction; and two adjacent third pin units are configured to transmit different high-speed differential signals.

In an embodiment, the second pin array region further includes:

preset pins located at other pin positions of the second pin array region.

In an embodiment, the preset pins include low-speed single-ended signal pins.

The present disclosure further provides a package substrate, including: a wiring layer and a pin arrangement structure, the wiring layer being connected to the pin arrangement structure; the pin arrangement structure being the pin arrangement structure in any one of the above embodiments.

The above package substrate adopts the pin arrangement structure in the present disclosure. Since the number of pins of the pin arrangement structure in the package substrate is reduced, the design cost of the package substrate is reduced, and the package substrate is optimized due to reduction of crosstalk.

In an embodiment, the wiring layer includes first signal lines, the first signal lines being configured to connect the high-speed single-ended signal pins; the first signal lines being located on a same wiring layer.

The above package substrate uses a same wiring layer to lead out the high-speed single-ended signals through the first signal lines, which minimizes crosstalk and impedance discontinuity of wiring on the package substrate, and helps to improve signal quality and ensure signal integrity.

The present disclosure further provides a package structure, including: a package substrate, the package substrate being the package substrate described above; and
a chip located on one side of the package substrate; the chip and the package substrate being connected through the wiring layer.

In the above package structure, the chip and the package substrate are connected through the wiring layer, and since the pin arrangement structure on the package substrate occupies a smaller pin arrangement area, crosstalk and impedance discontinuity of wiring on the package substrate can be minimized, which helps to improve signal quality and ensure signal integrity. The package structure using the package substrate achieves the same effect.

### BRIEF DESCRIPTION OF THE DRAWINGS

In order to more clearly illustrate the technical solutions in embodiments of the present disclosure or the conventional art, the accompanying drawings used in the description of the embodiments or the conventional art will be briefly introduced below. It is apparent that, the accompanying drawings in the following description are only some embodiments of the present disclosure, and other drawings can be obtained by those of ordinary skill in the art from the provided drawings without creative efforts.

FIG. 1 is a schematic structural diagram of an existing pin arrangement structure;

FIG. 2 is a schematic structural diagram of another existing pin arrangement structure;

FIG. 3 is a schematic structural diagram of a pin arrangement structure according to embodiments of the present disclosure;

FIG. 4 is a schematic structural diagram of another pin arrangement structure according to embodiments of the present disclosure;

FIG. 5 is a schematic structural diagram of yet another pin arrangement structure according to embodiments of the present disclosure;

FIG. 6 is a schematic structural diagram of yet another pin arrangement structure according to embodiments of the present disclosure;

FIG. 7 is a schematic structural diagram of yet another pin arrangement structure according to embodiments of the present disclosure;

FIG. 8 is a schematic structural diagram of a package structure according to embodiments of the present disclosure;

FIG. 9 is a schematic structural diagram of an existing pin arrangement structure;

FIG. 10 is a schematic structural diagram of another existing pin arrangement structure;

FIG. 11 is a schematic diagram of comparison of crosstalk simulation of an 8-layer single board of a pin arrangement structure according to embodiments of the present disclosure; and

FIG. 12 is a schematic diagram of comparison of eye-diagram simulation of an 8-layer single board of a pin arrangement structure according to embodiments of the present disclosure.

Reference signs: 01: first pin array region; 02: first pin unit; 03: second pin unit; 04: first reference ground pin; 05: second pin array region; 06: third pin unit; 07: second reference ground pin; 08: third reference ground pin; 09: preset pin; 10: third pin array region; 11: fourth pin unit; 12: fourth reference ground pin; 13: package substrate; 14: chip; 15: first signal line; 16: pin arrangement structure; 02a: first pin; 02b: second pin; 03c: third pin; 06a: fourth pin; 06b: fifth pin; 11a: sixth pin; 11b: seventh pin.

### DETAILED DESCRIPTION

To facilitate understanding of the present disclosure, a more comprehensive description of the present disclosure will be given below with reference to the relevant accompanying drawings. Preferred embodiments of the present disclosure are given in the drawings. However, the present disclosure may be implemented in many different forms and is not limited to the embodiments described herein. Rather, these embodiments are provided to make the contents disclosed in the present disclosure more fully understood.

Unless defined otherwise, all technical and scientific terms used herein have the same meanings as would generally understood by those skilled in the technical field of the present disclosure. The terms used herein in the specification of the present disclosure are for the purpose of describing specific embodiments only, and are not intended to limit the present disclosure.

It should be understood that when an element or layer is referred to as being “on”, “adjacent to”, or “connected to” another element or layer, the element or layer may be directly on, adjacent to, or connected to the another element or layer, or an intervening element or layer may be disposed therebetween. On the contrary, when an element is referred to as being “directly on”, “directly adjacent to”, or “directly connected to” another element or layer, no intervening element or layer may be disposed therebetween. It should be understood that although terms such as first, second, and third may be used to describe various regions, layers, or units, the regions, layers, or units may not be limited to such terms. Such terms are used only to distinguish one region, layer, or unit from another region, layer, or unit. Therefore, without departing from the teaching of the present disclosure, a first region, layer, or unit may be referred to as a second region, layer, or unit.

Spatial relationship terms such as “under”, “underneath”, “below”, “beneath”, “over”, and “above” may be used to describe a relationship between one element or feature and another element or feature illustrated in the figures. It should be understood that, in addition to the orientations illustrated in the figures, the spatial relationship terms are intended to further include different orientations of the device in use and operation. For example, if the device in the figures is flipped, the element or feature described as “below”, “underneath” or “under” another element or feature may be oriented as “on” the another element or feature. Thus, the exemplary terms “below” and “under” may include two orientations of above and below.

In use, the singular forms of “a/an”, “one”, and “the” may also include plural forms, unless otherwise clearly specified by the context. It should be further understood that the terms “include/comprise” and/or “have” specify the presence of the features, integers, steps, operations, components, portions, or their combinations, but may not exclude the presence or addition of one or more of other features, integers, steps, operations, components, portions, or their combinations. At the same time, in the specification, the term “and/or” may include any and all combinations of related listed items.

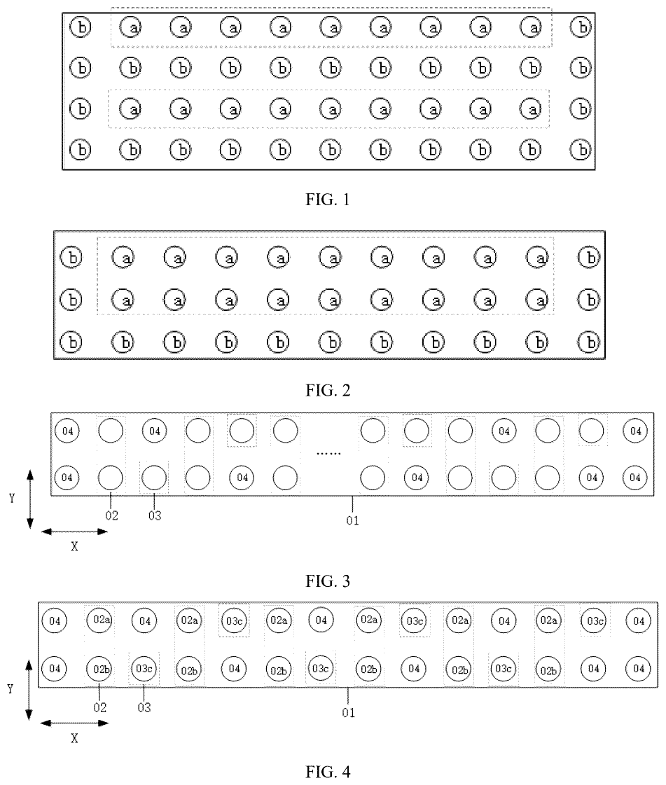

Based on the content in the Background, each byte high-speed data signal set of the high-speed DDR interface generally has 9 high-speed single-ended signal pins. Taking an X16-bit wide low power double data rate 5 (LPDDR5) protocol physical layer (PHY) as an example, each PHY has 2 bytes, including 18 high-speed single-ended signal pins (6.4 Gbps, Data). Referring to FIG. 1, FIG. 1 is a schematic structural diagram of an existing pin arrangement structure. High-speed single-ended signal pins a and reference ground pins b are regularly arranged according to a ratio of 2:1-1:1, and the high-speed single-ended signal pins a are isolated by the reference ground pins b. The arrangement can ensure signal quality and provide isolation between signals. However, a chip packaging area and a number of pins are limited. If each high-speed single-ended signal pin a is paired with one reference ground pin b, for a typical high-speed DDR interface, at least 4 rows are required to complete the arrangement of the high-speed single-ended signal pins a, and the number of pins may reach 44.

In order to reduce the number of pins, in the existing design, referring to FIG. 2, FIG. 2 is a schematic structural diagram of another existing pin arrangement structure. The high-speed single-ended signal pins a are arranged in an array, and no reference ground pins b are designed between adjacent high-speed single-ended signal pins a. In this way, one rows of reference ground pins b can be saved, the arrangement of the high-speed single-ended signal pins a can be completed with 3 rows, and the number of pins may reach 33. Although the number of pins is reduced compared to the arrangement in FIG. 1, due to the absence of the reference ground pins b between the high-speed single-ended signal pins a, the crosstalk is greater, which may lead to a failure to reach a maximum operating rate of some DDR interface protocols (such as LPDDR5, 6.4 Gbps).

Based on this, the present disclosure provides a schematic structural diagram of a pin arrangement structure. The pin arrangement structure includes a first pin array region. First pin units and second pin units in the first pin array region are sequentially arranged alternately in a first direction, and the first pin units and the second pin units are both provided with high-speed single-ended signal pins. A number of pins of the first pin units in a second direction is greater than a number of pins of the second pin units in the second direction, two adjacent second pin units are staggered in the first direction, and first reference ground pins are arranged at other pin positions of the first pin array region. Therefore, isolation is formed between the high-speed single-ended signal pins, improving isolation between signals and reducing crosstalk between the signals. At the same time, compared with existing arrangement, the arrangement reduces the number of pins and saves a region area of the pins.

In order to make the above objectives, features, and advantages of the present disclosure more obvious and understandable, the present disclosure will be further described in detail below in conjunction with the accompanying drawings and specific implementations.

Referring to FIG. 3, FIG. 3 is a schematic structural diagram of a pin arrangement structure according to embodiments of the present disclosure. The pin arrangement structure includes a first pin array region 01. The first pin array region 01 includes: first pin units 02 and second pin units 03 sequentially arranged alternately in a first direction X. The first pin units 02 and the second pin units 03 are both provided with high-speed single-ended signal pins, and a number of pins of the first pin units 02 in a second direction is greater than a number of pins of the second pin units 03 in the second direction Y. Two adjacent second pin units 03 are staggered in the first direction X. First reference ground pins 04 are arranged at other pin positions of the first pin array region 01.

Specifically, in embodiments of the present disclosure, as shown in FIG. 3, the first pin array region 01 is arranged in an array in the first direction X and the second direction Y. It is to be noted that the first direction X and the second direction Y are both located in a same plane, and the first direction X and the second direction Y are arranged perpendicularly to each other. The first pin array region 01 includes a plurality of first pin units 02, a plurality of second pin units 03, and a plurality of first reference ground pins 04.

It is to be noted that the number and connection points of pins in the first pin unit 02 and the second pin unit 03 are not specifically limited. Each pin in the first pin unit 02 and the second pin unit 03 may be used as a high-speed single-ended signal pin. Unit division thereof is only to better illustrate the arrangement structure.

It is to be noted that the number of pins of the first pin unit 02 in the second direction Y is greater than the number of pins of the second pin unit 03 in the second direction Y, and two adjacent second pin units 03 are staggered in the first direction X. In this way, when the first reference ground pin 04 is arranged, the first reference ground pin 04 is inserted between the first pin unit 02 and the second pin unit 03, thereby improving isolation between different high-speed single-ended signal pins and reducing signal crosstalk.

In an embodiment, the number of pins of the first pin unit 02 in the first direction X is the same as the number of pins of the second pin unit 03 in the first direction X. For example, in the first direction X, the numbers of pins of the first pin unit 02 and the second pin unit 03 are both one. The number of pins of the first pin unit 02 in the second direction Y is greater than the number of pins of the second pin unit 03 in the second direction Y. For example, in the second direction Y, the number of pins of the first pin unit 02 is two, and the number of pins of the second pin unit 03 is one.

Each byte of the high-speed DDR interface generally has 9 high-speed single-ended signals. Taking an X16-bit wide LPDDR5 protocol PHY as an example below, each PHY has 2 bytes, including 18 high-speed single-ended signal pins. Referring to FIG. 4, FIG. 4 is a schematic structural diagram of another pin arrangement structure according to embodiments of the present disclosure. The first pin unit 02 has two pins in the second direction Y, the first pin unit 02 has one pin in the first direction X, the second pin unit 03 has one pin in the second direction Y, and the number of pins of the second pin unit 03 in the first direction X is one. The first pin unit 02 includes first pins 02a and second pins 02b. The first pins 02a and the second pins 02b are arranged sequentially in the second direction Y. The second pin unit 03 includes third pins 03c, and two adjacent second pin units 03 are staggered in the first direction X. That is, the third pins 03c are staggered in the first direction X. When an i^{th} third pin 03c is in a same row as the first pin 02a, an i+1^{th} third pin 03c is in a same row as the second pin 02b, where i≥1 and i is a positive integer, which is not specifically limited herein. In this case, the third pin 03c is located in a same column as the first reference ground pin 04 and is located between two adjacent first pin units 02.

The first pin 02a, the second pin 02b, and the third pin 03c are all high-speed single-ended signal pins. In this case, a total number of pins of the first reference ground pin 04, the first pin 02a, the second pin 02b, and the third pin 03c corresponding thereto is 28. Compared with the arrangement in FIG. 1, the number of pins is reduced, and the arrangement of the number of pins is saved. Compared with the arrangement in FIG. 2, the number of pins is reduced, isolation between signals is improved, and occurrence of signal crosstalk is reduced.

In the above example, the number of pins of the first pin units 02 in the second direction Y is greater than the number of pins of the second pin units 03 in the second direction Y, two adjacent second pin units 03 are staggered in the first direction X, and the first reference ground pins 04 are arranged at other pin positions of the first pin array region 01. Therefore, isolation is formed between the high-speed single-ended signal pins, improving isolation between signals and reducing crosstalk between the signals. At the same time, compared with existing arrangement, the arrangement reduces the number of pins and saves a region area of the pins.

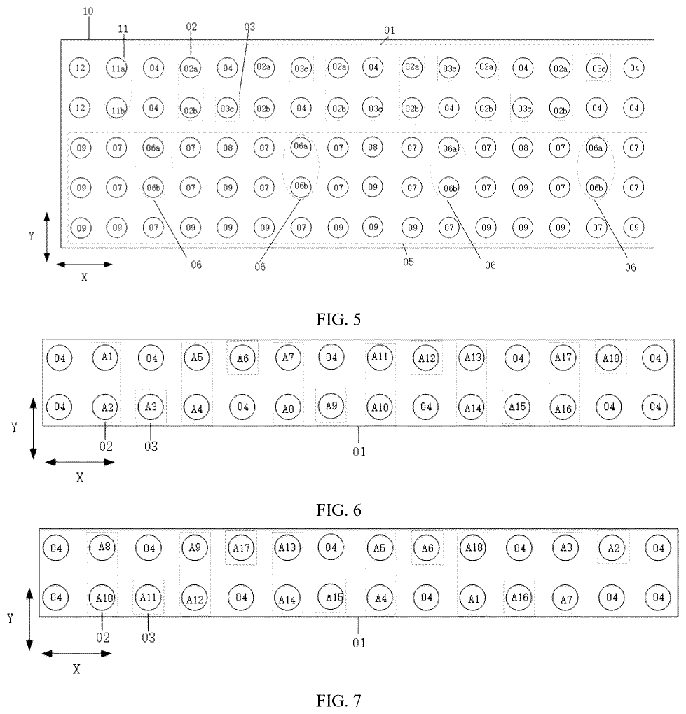

Optionally, in another embodiment of the present disclosure, referring to FIG. 5, FIG. 5 is a schematic structural diagram of yet another pin arrangement structure according to embodiments of the present disclosure. The pin arrangement structure further includes: a second pin array region 05 located on one side of the first pin array region 01. The second pin array region 05 includes:
at least one third pin unit 06, the third pin unit 06 being provided with high-speed differential signal pins, and the third pin unit 06 being adjacent to the first reference ground pins 04 in the second direction Y; and
second reference ground pins 07 surrounding the third pin unit 06 jointly with the first reference ground pins 04.

Specifically, one side of the first pin array region 01 of the pin arrangement structure further includes a second pin array region 05, the second pin array region 05 includes at least one third pin unit 06, and each third pin unit 06 is provided with a high-speed differential signal pin.

In order to ensure symmetry of a reflow structure of high-speed differential signals, the third pin unit 06 is required to be surrounded by reference ground pins. In the second direction Y, the third pin unit 06 is arranged adjacent to the first reference ground pin 04, which can save a position of one reference ground pin, and then the second reference ground pin 07 is arranged around the third pin unit 06 so that the second reference ground pin 07 and the first reference ground pin 04 jointly surround the third pin unit 06, which ensures the symmetry of the reflow structure of the high-speed differential signals and also ensures isolation between the signals.

Optionally, in another embodiment of the present disclosure, when a plurality of third pin units 06 are provided, the plurality of third pin units 06 are arranged at intervals in the first direction X, and two adjacent third pin units 06 are configured to transmit different high-speed differential signals.

Specifically, each byte of the high-speed DDR interface generally has 1 to 2 pairs of high-speed differential signals and 9 high-speed single-ended signals. Taking an X16-bit wide LPDDR5 protocol PHY as an example, each PHY has 2 bytes, including 4 pairs of high-speed differential signals (3.2 GHZ, Data Strobe), that is, 4 third pin units 06. Each third pin unit 06 includes a fourth pin 06a and a fifth pin 06b. The fourth pin 06a includes a first high-speed differential signal pin, the fifth pin 06b includes a second high-speed differential signal pin, the first high-speed differential signal pin and the second high-speed differential signal pin are respectively a positive high-speed differential signal pin and a negative high-speed differential signal pin, and the two pins are arranged sequentially in the second direction Y. For example, the first high-speed differential signal pin may be a WCKP positive high-speed differential signal pin, the second high-speed differential signal pin may be a WCKM negative high-speed differential signal pin, and the WCKP positive high-speed differential signal pin and the WCKM negative high-speed differential signal pin are arranged sequentially in the second direction Y. Additionally/alternatively, the first high-speed differential signal pin may be a DQSP positive high-speed differential signal pin, the second high-speed differential signal pin may be a DQSM negative high-speed differential signal pin, and the DQSP positive high-speed differential signal pin and the DQSM negative high-speed differential signal pin are arranged sequentially in the second direction Y.

When a plurality of third pin units 06 are provided, the plurality of third pin units 06 are arranged at intervals in the first direction X, and two adjacent third pin units 06 are different. For example, in the first direction X, two different third pin units 06 are arranged alternately twice to form a pin arrangement as shown in FIG. 5. It is to be noted that the third pin unit 06 is not specifically limited, which may be arranged according to a specific requirement.

In this case, the second reference ground pin 07 and the first reference ground pin 04 jointly surround the third pin unit 06, and the second reference ground pin 07 and the first reference ground pin 04 form a hexagonal arrangement. Since one second reference ground pin 07 is replaced with one first reference ground pin 04, the number of pins in the pin arrangement structure is further reduced.

Optionally, in another embodiment of the present disclosure, as shown in FIG. 5, the second pin array region 05 further includes: third reference ground pins 08, and the third reference ground pins 08 are adjacent to the second pin units 03 in the second direction Y.

Specifically, the second pin array region 05 further includes third reference ground pins 08, and the third reference ground pins 08 are adjacent to the second pin units 03. In this case, a ratio of each high-speed single-ended signal pin to the reference ground pin in the first pin unit 02 and the second pin unit 03 is close to 1:1, which can increase isolation between the signals and reduce occurrence of crosstalk.

Optionally, in another embodiment of the present disclosure, as shown in FIG. 5, the second pin array region 05 further includes:
preset pins 09 located at other pin positions of the second pin array region 05.

Optionally, in another embodiment of the present disclosure, the preset pins 09 include low-speed single-ended signal pins.

Specifically, in the second pin array region 05, except for the third pin unit 06, the second reference ground pin 07, and the third reference ground pin 08, other pin positions may be used as the preset pins 09. The preset pins 09 may be provided as low-speed single-ended signal pins, including, but not limited to, control signals, command signals, address signals, and the like. It is to be noted that the preset pins 09 are not specifically limited, and the preset pins may alternatively be used as other signal pins according to a requirement. The arrangement of the preset pins 09 may allow the pin arrangement structure to have higher design performance.

Optionally, in another embodiment of the present disclosure, as shown in FIG. 5, the pin arrangement structure further includes: a third pin array region 10, and the third pin array region 10 includes the first pin array region 01 and the second pin array region 05.

The third pin array region 10 further includes fourth pin units 11 and fourth reference ground pins 12, the fourth pin units 11 are provided with differential signal pins, and the fourth reference ground pins 12 surround the fourth pin units 11; or the fourth reference ground pins 12 surround the fourth pin units 11 jointly with the second reference ground pins 07 and/or the first reference ground pins 04.

Specifically, the pin arrangement structure further includes a third pin array region 10, the third pin array region 10 includes the first pin array region 01 and the second pin array region 05, and in the third pin array region 10, the fourth pin unit 11 is inserted between the first pin array region 01 and the second pin array region 05. That is, the position of the fourth pin unit 11 is not specifically limited.

The fourth pin unit 11 includes differential signal pins. The fourth pin unit 11 includes sixth pins 11a and seventh pins 11b. The sixth pins 11a may be positive differential signal pins, the seventh pins 11b may be negative differential signal pins, and the positive differential signal pins and the negative differential signal pins are arranged sequentially in the second direction Y. In this case, in order to reduce the arrangement of the pins, the fourth pin unit 11 is inserted between the first pin array region 01 and the second pin array region 05, as long as the reference ground pin surrounds the fourth pin unit 11. For example, as shown in FIG. 5, one side of the fourth pin unit 11 is adjacent to the second reference ground pin 07, the other side is adjacent to the first reference ground pin 04, and the remaining sides are provided with fourth reference ground pins 12, so that the fourth reference ground pin 12 surrounds the fourth pin unit 11 jointly with the second reference ground pin 07 and the first reference ground pin 04.

Alternatively, the fourth pin unit 11 may be surrounded by only the fourth reference ground pin 12, or the fourth reference ground pin 12 and the second reference ground pin 07 jointly surround the fourth pin unit 11, or the fourth reference ground pin 12 and the first reference ground pin 04 jointly surround the fourth pin unit 11, and so on, as long as the reference ground pin surrounds the fourth pin unit 11, which is not specifically limited. When the pin is close to an edge and there are no adjacent pin positions, adjacent ground pins may not be arranged. Such an arrangement structure can further reduce the number of pins, thereby reducing an area of the pin arrangement structure.

It is to be noted that when the fourth reference ground pin 12 surrounds the fourth pin unit 11 jointly with the second reference ground pin 07 and the first reference ground pin 04, the number of pins occupied by the pin arrangement structure is minimal, which further saves the design of the number of pins.

Based on the design of the pin arrangement structure above, the present disclosure further provides a package substrate. The package substrate includes: a wiring layer and a pin arrangement structure. The wiring layer is connected to the pin arrangement structure. The pin arrangement structure is the pin arrangement structure in any one of the above embodiments.

Specifically, the package substrate includes a wiring layer and a pin arrangement structure. For example, the package substrate may be a printed circuit board (PCB). It is to be noted that, on the PCB, positions of high-speed single-ended signal pins in the pin arrangement structure may be arranged according to a requirement, and the position of each high-speed single-ended signal pin is not limited. Taking an X16-bit wide LPDDR5 protocol PHY as an example, each PHY has 2 bytes, including 4 pairs of high-speed differential signals (3.2 GHZ, Data Strobe) and 18 high-speed single-ended signal pins (6.4 Gbps, Data). Positions of the 18 high-speed single-ended signal pins A1-A18 may be continuous signals along a serpentine structure. Referring to FIG. 6, FIG. 6 is a schematic structural diagram of yet another pin arrangement structure according to embodiments of the present disclosure. Discontinuous arrangement may be alternative. Referring to FIG. 7, FIG. 7 is a schematic structural diagram of yet another pin arrangement structure according to embodiments of the present disclosure. The high-speed single-ended signal pins may be sequentially numbered arbitrarily, making the subsequent connecting design easier.

Optionally, in another embodiment of the present disclosure, the wiring layer includes first signal lines, the first signal lines are configured to connect the high-speed single-ended signal pins, and the first signal lines are located on a same wiring layer.

Specifically, in the wiring structure of this embodiment, an advanced laser drilling process may be used for wiring, and the first signal lines connecting the high-speed single-ended signal pins in the wiring layer are located on a same layer, which can effectively reduce the number of signal layers required for wiring of the package structure and reduce the manufacturing cost of the package structure. For example, in the embodiments of the present disclosure, design structures of wiring layers of two package structures, i.e., a 6-layer single board and an 8-layer single board, are provided as in Table 1 and Table 2 below. Table 1 is the wiring layer of the 6-layer single board, and Table 2 is the wiring layer of the 8-layer single board.

TABLE 1

| | | | Recommended | |
|---|---|---|---|---|
| Wiring | | | minimum line spacing | |
| layer | Wiring type | Signal | (side-to-side distance) | Wiring impedance |
| L1 | Microstrip | Data | 3W | Combined with relevant |
| | line | | | agreement requirements |
| L4 | Strip line | Command, Address | 3W | Combined with relevant |
| | | | | agreement requirements |
| L6 | Microstrip | Data Strobe | 3W | Combined with relevant |
| | line | | | agreement requirements |

TABLE 2

| | | | Recommended | |
|---|---|---|---|---|
| Wiring | | | minimum line spacing | |
| layer | Wiring type | Signal | (side-to-side distance) | Wiring impedance |
| L2 | Strip line | Data | 3W | Combined with relevant |
| | | | | agreement requirements |
| L5 | Strip line | Command, Address | 3W | Combined with relevant |
| | | | | agreement requirements |
| L7 | Strip line | Data Strobe | 3W | Combined with relevant |
| | | | | agreement requirements |

In Table 1 and Table 2, Data denotes high-speed single-ended signals, Data Strobe denotes high-speed differential signals, Command denotes control signals, and Address denotes address signals. Obviously, in the 6-layer single board, the high-speed single-ended signals Data may be located on the same layer, that is, on the first layer L1. In the 8-layer single board, the high-speed single-ended signals Data may be located on the same layer, that is, on the second layer L2. The arrangement of the high-speed single-ended signals Data on the same layer reduces the manufacturing cost of the package structure.

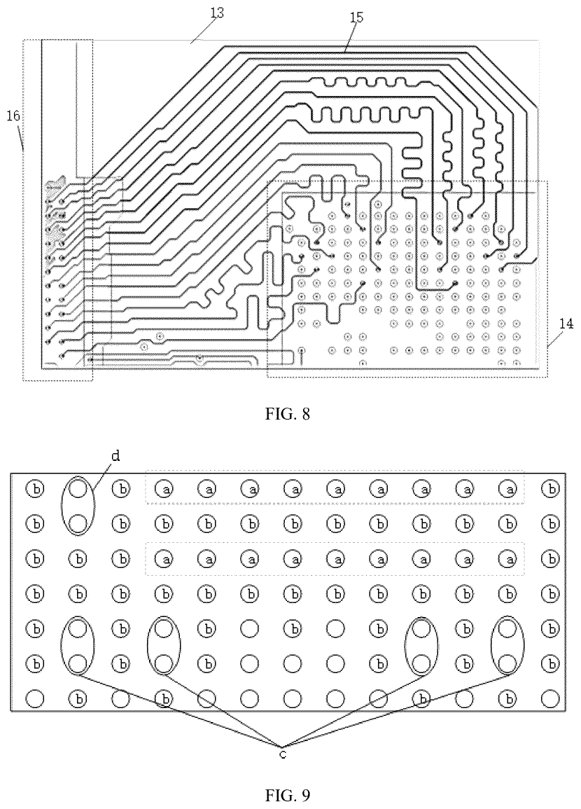

Optionally, in another embodiment of the present disclosure, a package structure is further provided. Referring to FIG. 8, FIG. 8 is a schematic structural diagram of a package structure according to embodiments of the present disclosure, including: a package substrate 13, and a chip 14 located on one side of the package substrate 13. The chip 14 and the package substrate 13 are connected through the wiring layer.

Specifically, the package substrate 13 may be a PCB, and the chip 14 may be a synchronous dynamic random-access memory (SDRAM). The PCB is connected to a SDRAM signal through a first signal line 15. A pin arrangement structure 16 on the PCB is the pin arrangement structure in the above embodiments. Since the pin arrangement structure has fewer pins, an area occupied by the pins is reduced, and since isolation between signals in the pin arrangement structure is optimized, crosstalk is reduced, allowing signals between the package substrate 13 and the chip 14 in the package structure to be more complete. Since pin positions of the high-speed single-ended signal pins in the package substrate 13 may be changed arbitrarily in the arrangement of the serpentine structure, the shortest connecting line may be used to complete interconnection between a controller and the SDRAM on the PCB, thereby maximizing reducing the crosstalk and impedance discontinuity of wiring on the PCB and improving signal quality of the package structure.

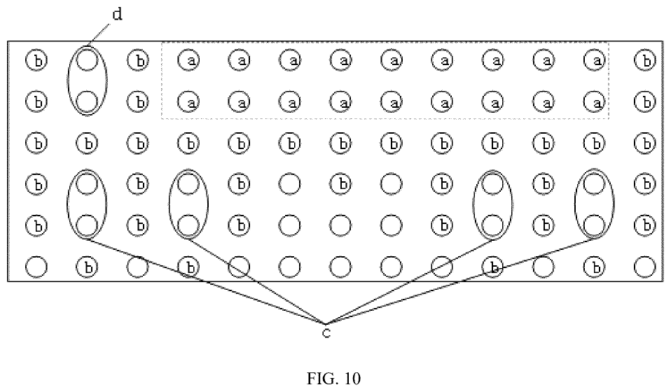

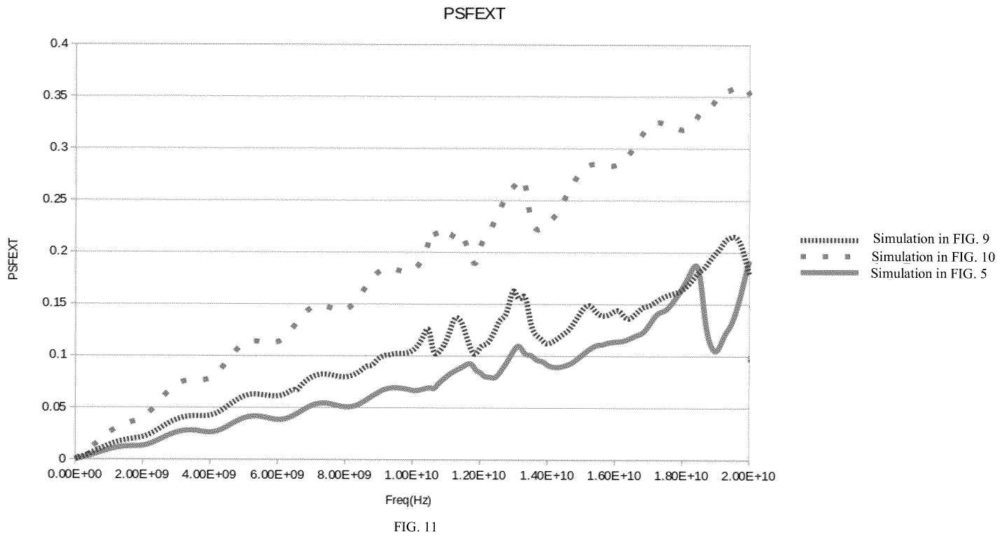

Based on the above package structure, in the present disclosure, PCB wiring crosstalk characteristics and eye patterns of the structure of the 8-layer single board using the above pin arrangement structure and the existing two pin arrangement structures are simulated and compared. Referring to FIG. 9, FIG. 9 is a schematic structural diagram of an existing pin arrangement structure, which occupies a rectangular area corresponding to 91 pins. Referring to FIG. 10, FIG. 10 is a schematic structural diagram of another existing pin arrangement structure, which occupies a rectangular area corresponding to 78 pins. a is a high-speed single-ended signal pin, b is a reference ground pin, c is a high-speed differential signal pin, and d is a differential signal pin. In the following simulation comparison, the existing structure uses two different existing pin arrangement structures in FIG. 9 and FIG. 10 for simulation. In the present disclosure, the pin arrangement in FIG. 5 is used for simulation.

The structure of the 8-layer single board used in the simulation is shown in Table 3 below. Table 3 shows a laminated structure of an 8-layer PCB. Serial numbers 1 to 8 from top to bottom represent a first metal wiring layer (conductor) to an eighth metal wiring layer (conductor). Solder mask (SM) represents a solder mask layer. Pre-preg (PP) between the metal wiring layers (conductors) represents a dielectric material prepreg, which is used for dielectric isolation between the metal wiring layers that make up a laminate. Core between the metal wiring layers (conductors) is a core board. Copper foil types of the first metal wiring layer and the eighth metal wiring layer are HTE, and copper foil types from the second metal wiring layer to the seventh metal wiring layer are RTF. RTF has lower surface roughness. Copper thicknesses of the first metal wiring layer and the eighth metal wiring layer are 0.333 Oz+Plating. Oz denotes a thickness of base copper, and Plating denotes an electroplating layer on the base copper. Copper thicknesses from the second metal wiring layer to the seventh metal wiring layer are all 1 Oz. Dielectric constant (DK) denotes a dielectric constant of a material, and dissipation factor (DF) denotes a dielectric loss factor.

TABLE 3

| Serial | | | | Copper | Thickness/ | Copper |
|---|---|---|---|---|---|---|
| [symbol] | Layer | DK | DF | thickness/Oz | mil | [symbol] |
| | SM | 3.3 | 0.02 | | 0.5 | |
| 1 | Conductor | | | 0.333 0z + | 1.8 | HTE |
| | | | | plating | | |
| | PP | 4.1 | 0.015 | | 2.4 | |
| 2 | Conductor | | | 1 | 1.2 | RTF |
| | Core | 4.1 | 0.015 | | 8 | |
| 3 | Conductor | | | 1 | 1.2 | RTF |
| | PP | 4.1 | 0.015 | | 3.8 | |
| 4 | Conductor | | | 1 | 1.2 | RTF |
| | Core | 4.4 | 0.015 | | 21 | |
| 5 | Conductor | | | 1 | 1.2 | RTF |
| | PP | 4.1 | 0.015 | | 3.8 | |
| 6 | Conductor | | | 1 | 1.2 | RTF |
| | Core | 4.1 | 0.015 | | 8 | |
| 7 | Conductor | | | 1 | 1.2 | RTF |
| | PP | 4.1 | 0.015 | | 2.4 | |
| 8 | Conductor | | | 0.333 0z + | 1.8 | HTE |
| | | | | plating | | |
| | SM | 3.3 | 0.02 | | 0.5 | |

[symbol]

indicates data missing or illegible when filed

The pin arrangement of the 8-layer PCB board adopts three different pin arrangements to obtain three 8-layer PCB boards and simulate them. The simulation is carried out using Cadence Clarity3D full-wave electromagnetic simulation software and TopXP channel simulation software. A frequency-domain simulation band ranges from 10 MHz to 20 GHz.

Referring to FIG. 11, FIG. 11 is a schematic diagram of comparison of crosstalk simulation of an 8-layer single board of a pin arrangement structure according to embodiments of the present disclosure. The worst PSFEXT line in one DDR Byte (8 lines) is taken for comparison. FIG. 11 includes a simulation curve in FIG. 5 of the present disclosure, an existing simulation curve in FIG. 9, and an existing simulation curve in FIG. 10. The simulation curve in FIG. 5 is a crosstalk simulation curve of the pin arrangement structure provided in the present disclosure. The simulation curve in FIG. 9 and the simulation curve in FIG. 10 are crosstalk simulation curves of the existing pin arrangement structure. As can be seen, the crosstalk of the pin arrangement structure provided in the present disclosure is significantly lower than that of the arrangement shown in FIG. 9 and FIG. 10. Since the frequency-domain simulation band ranges from 10 MHz to 20 GHz, for a crosstalk index, a lower curve value at a same frequency point indicates better performance. Therefore, the pin arrangement structure in the present disclosure has the advantage of the crosstalk index.

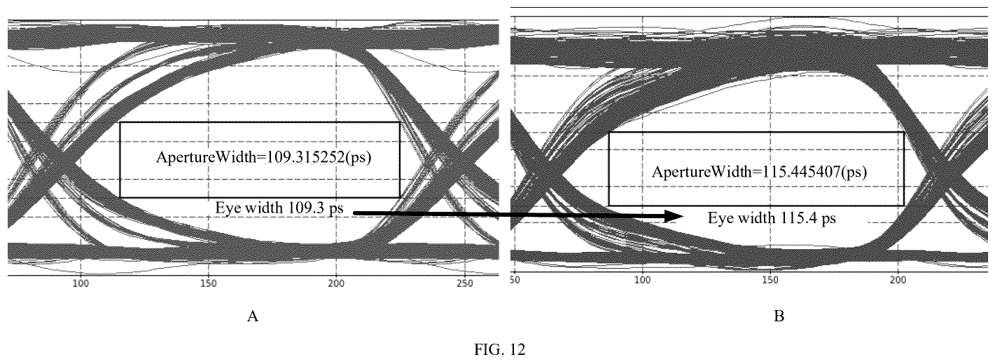

Referring to FIG. 12, FIG. 12 is a schematic diagram of comparison of eye-diagram simulation of an 8-layer single board of a pin arrangement structure according to embodiments of the present disclosure. In FIG. 12, A is an eye-diagram simulation curve of the pin arrangement structure in FIG. 9, and B is an eye-diagram simulation curve of the pin arrangement structure provided in the present disclosure. Obviously, an eye width of the eye-diagram simulation curve of the pin arrangement structure provided in the present disclosure increases by 6.1 ps. Since the frequency-domain simulation band ranges from 10 MHz to 20 GHz, for an eye-diagram index, a wider eye width indicates better performance, so the pin arrangement structure in the present disclosure is obviously better.

Therefore, the pin arrangement structure provided in the present disclosure is obviously better than the existing pin arrangement structure, and a degree of signal isolation in the present disclosure is high, which can effectively reduce crosstalk performance without significantly increasing the number of pins occupied by the DDR interface, helping to improve signal quality and ensure signal integrity. The arrangement ensures that signals use reference ground pins to isolate high-speed single-ended signals and high-speed differential signals, reduces the number of the reference ground pins used, and achieves better crosstalk performance and PCB cost benefits.

The package substrate and package structure provided in the present disclosure adopt the pin arrangement structure, which minimizes crosstalk and impedance discontinuity of wiring on the PCB, improves signal quality of the package structure, and has certain PCB design cost advantages.

In the description of the specification, reference terms such as “some embodiments” and “other embodiments” mean that a particular feature, structure, material, or characteristic described in connection with the embodiment or example is included in at least one embodiment or example of the present disclosure. In the specification, illustrative descriptions of the above terms are not necessarily referring to the same embodiment or example.

The technical features in the above embodiments may be randomly combined. For concise description, not all possible combinations of the technical features in the above embodiments are described. However, all the combinations of the technical features are to be considered as falling within the scope described in this specification provided that they do not conflict with each other.

The above embodiments only describe several implementations of the present disclosure, and their description is specific and detailed, but cannot therefore be understood as a limitation on the patent scope of the present disclosure. It should be noted that those of ordinary skill in the art may further make variations and improvements without departing from the conception of the present disclosure, all of which fall within the protection scope of the present disclosure. Therefore, the patent protection scope of the present disclosure should be subject to the appended claims.

1. A pin arrangement structure, comprising a first pin array region, the first pin array region comprising: first pin units and second pin units sequentially arranged alternately in a first direction; the first pin units and the second pin units being both provided with high-speed single-ended signal pins, a number of pins of the first pin units in a second direction being greater than a number of pins of the second pin units in the second direction, two adjacent second pin units being staggered in the first direction, and first reference ground pins being arranged at other pin positions of the first pin array region.

2. The pin arrangement structure according to claim 1, wherein the pin arrangement structure further comprises: a second pin array region located on one side of the first pin array region, the second pin array region comprising:
at least one third pin unit, the third pin unit being provided with high-speed differential signal pins, and the third pin unit being adjacent to the first reference ground pins in the second direction;
second reference ground pins surrounding the third pin unit jointly with the first reference ground pins.

3. The pin arrangement structure according to claim 2, wherein the second pin array region further comprises: third reference ground pins, the third reference ground pins being adjacent to the second pin units in the second direction.

4. The pin arrangement structure according to claim 3, wherein the pin arrangement structure further comprises: a third pin array region, the third pin array region comprising the first pin array region and the second pin array region;
the third pin array region further comprises fourth pin units and fourth reference ground pins, the fourth pin units being provided with differential signal pins, and the fourth reference ground pins surrounding the fourth pin units; or the fourth reference ground pins surround the fourth pin units jointly with the second reference ground pins and/or the first reference ground pins.

5. The pin arrangement structure according to claim 3, wherein the second pin array region further comprises:
preset pins located at other pin positions of the second pin array region.

6. The pin arrangement structure according to claim 5, wherein the preset pins comprise low-speed single-ended signal pins.

7. The pin arrangement structure according to claim 2, wherein when a plurality of third pin units are provided, the plurality of third pin units are arranged at intervals in the first direction;
and two adjacent third pin units are configured to transmit different high-speed differential signals.

8. A package substrate, comprising:
a wiring layer and a pin arrangement structure, the wiring layer being connected to the pin arrangement structure; the pin arrangement structure being the pin arrangement structure according to claim 1.

9. The package substrate according to claim 8, wherein the wiring layer comprises first signal lines, the first signal lines being configured to connect the high-speed single-ended signal pins; the first signal lines being located on a same wiring layer.

10. A package structure, comprising:
a package substrate, the package substrate being the package substrate according to claim 8;
a chip located on one side of the package substrate; the chip and the package substrate being connected through the wiring layer.
